(19) United States
(12) Patent Application Publication
(10) Pub. No.: US 2022/0232742 A1
(43) Pub. Date: Jul. 21, 2022

(54) AUDIO DEVICE, ELECTRONIC CIRCUIT, AND RELATED METHODS OF MANUFATURING

(71) Applicant: GN Hearing A/S, Ballerup (DK)

(72) Inventors: Thorvaldur Oli BODVARSSON, Ballerup (DK); Kamila PIOTROWSKA, Ballerup (DK); Henrik SCHULTZ-MIKKELSEN, Ballerup (DK); Michael SKOVDAL-OLSEN, Ballerup (DK)

(73) Assignee: GN Hearing A/S, Ballerup (DK)

(21) Appl. No.: 17/714,138

(22) Filed: Apr. 5, 2022

Related U.S. Application Data
(63) Continuation of application No. PCT/EP2020/078448, filed on Oct. 9, 2020.

(30) Foreign Application Priority Data
Oct. 25, 2019 (EP) 19205409.6

(51) Int. Cl. H05K 9/00; H05K 3/28; H05K 1/02; H04R 25/00

(52) U.S. Cl. CPC H05K 9/0024; H05K 3/284; H05K 1/0216; H05K 2203/1322; H04R 25/609; H04R 2225/49; H05K 1/0215

(57) ABSTRACT

Audio device, electronic circuit, and related methods, in particular a method of manufacturing an electronic circuit for an audio device is disclosed, the method comprising providing a circuit board; mounting one or more electronic components including a first electronic component on the circuit board; applying a first insulation layer outside the first electronic component; and applying a first shielding layer outside the first insulation layer.

### RELATED APPLICATION DATA

This application is a continuation of International Patent Application No. PCT/EP2020/078448 filed on Oct. 9, 2020, which claims priority to, and the benefit of, European Patent Application No. 19205409.6 filed on Oct. 25, 2019. The entire disclosures of the above applications are expressly incorporated by reference herein.

### FIELD

The present disclosure relates to an audio device, electronic circuit, and related methods, in particular a method of manufacturing an electronic circuit for an audio device.

### BACKGROUND

Audio devices comprising electronic circuits with electronic components may often be exposed to electromagnetic fields disturbing the operation of electronic components of the electronic circuit. It is therefore desirable to shield the electronic components of the electronic circuits from these electromagnetic fields. Today the shielding of electronic devices in audio devices is performed with shielding cans such as with folded sheets of metal. These shielding cans need clearance to the electronic components, which results in voluminous and cumbersome shielding in the audio devices.

### SUMMARY

Accordingly, there is a need for audio devices and methods of manufacturing audio devices with improved insulation and/or shielding.

A method of manufacturing an electronic circuit of an audio device is disclosed, the method comprising providing a circuit board; mounting one or more electronic components including a first electronic component on the circuit board; applying a first insulation layer, e.g. outside the first electronic component and/or on the circuit board; and applying a first shielding layer, e.g. outside the first insulation layer and/or on the circuit board.

Further, an audio device is disclosed, the audio device comprising a housing and an electronic circuit accommodated in the housing, the electronic circuit comprising a circuit board and one or more electronic components including a first electronic component mounted on the circuit board, the electronic circuit comprising a first insulation layer and a first shielding layer covering the first electronic component, the first insulation layer is arranged, e.g. partly or fully arranged, between the first electronic component and the first shielding layer, wherein the first insulation layer optionally has a thickness, such as a first thickness, less than 500 μm, micrometre.

Also disclosed is an electronic circuit for an audio device, the electronic circuit comprising a circuit board and one or more electronic components including a first electronic component mounted on the circuit board, the electronic circuit comprising a first insulation layer and a first shielding layer covering the first electronic component, the first insulation layer arranged, e.g. partly or fully arranged, between the first electronic component and the first shielding layer, wherein the first insulation layer optionally has a thickness, such as a first thickness, less than 500 μm.

It is an advantage of the present disclosure that the shielding of the one or more electronic components of the electronic circuit is improved while an increased design flexibility of the audio device is achieved.

Further, a combination of a first insulation layer outside the first electronic component, and

a first shielding layer outside the first insulation layer, reduces the size of the shielding of the electronic circuit, thereby also reducing the size of the electronic circuit, and in turn the size of the audio device, while providing a reliable insulation and shielding of the electronic component.

A further advantage is that the shielding of the electronic component may be improved and adapted to the electronic component to be shielded, thereby providing an improved and more reliable shielding.

A further advantage of the present disclosure is that the shielding of the electronic components is minimized, whereby more compact electronic circuits may be provided, and thus also more compact audio devices. A further advantage is that the weight of the electronic circuit may be reduced e.g. because of reduced amounts of material used.

### BRIEF DESCRIPTION OF THE DRAWINGS

The above and other features and advantages will become readily apparent to those skilled in the art by the following detailed description of exemplary embodiments thereof with reference to the attached drawings, in which:

FIG. 1 schematically illustrates parts of exemplary electronic circuits according to the disclosure,

FIG. 2 schematically illustrates parts of exemplary electronic circuits according to the disclosure,

FIG. 3 schematically illustrates parts of exemplary electronic circuits according to the disclosure,

FIG. 4 schematically illustrates parts of exemplary electronic circuits according to the disclosure,

FIG. 5 schematically illustrates parts of exemplary electronic circuits according to the disclosure,

FIG. 6 schematically illustrates parts of exemplary electronic circuits according to the disclosure,

FIG. 7 shows a cross section of exemplary electronic circuits according to the disclosure,

FIG. 8 shows a cross section of exemplary electronic circuits according to the disclosure,

FIG. 9 is a flow chart of exemplary method according to the disclosure,

FIG. 10 shows a cross section of exemplary electronic circuits according to the disclosure,

FIG. 11 shows a cross section of exemplary electronic circuits according to the disclosure,

FIG. 12 schematically illustrates parts of exemplary electronic circuits according to the disclosure,

FIG. 13 shows an exemplary audio device, and

FIG. 14 shows alternative ground connection.

### DETAILED DESCRIPTION

Various exemplary embodiments and details are described hereinafter, with reference to the figures when relevant. It should be noted that the figures may or may not be drawn to scale and that elements of similar structures or functions are represented by like reference numerals throughout the figures. It should also be noted that the figures are only intended to facilitate the description of the embodiments. They are not intended as an exhaustive description of the invention or as a limitation on the scope of the invention. In addition, an illustrated embodiment needs not have all the aspects or advantages shown. An aspect or an advantage described in conjunction with a particular embodiment is not necessarily limited to that embodiment and can be practiced in any other embodiments even if not so illustrated, or if not so explicitly described.

In the present disclosure, whenever referring to a proximal side of a component, layer, an element, a device or part of a device, the referral is to the side of the component, layer, element, device or part thereof closest to the circuit board. Further, whenever referring to a proximal surface of a component, layer, an element, a device or part of a device, the referral is to the surface of the component, layer, element, device or part thereof facing the circuit board. Likewise, whenever referring to the distal side of a component, layer, an element, a device or part of a device, the referral is to the side furthest away from the circuit board. Further, whenever referring to a distal surface of a component, layer, an element, a device or part of a device, the referral is to the surface of the component, layer, element, device or part thereof facing away from the circuit board. In other words, the proximal side or surface is the side or surface closest to the circuit board and the distal side is the opposite side or surface—the side or surface furthest away from the circuit board.

A method of manufacturing an electronic circuit of an audio device is disclosed. The method comprises providing a circuit board. The circuit board may e.g. be a printed circuit board, PCB, the circuit board may e.g. be configured to mechanically support and electrically connect one or more electronic components or electrical components using e.g. conductive tracks or pads. The circuit board may comprise one or more sheet layers of a conductive layer, laminate, or film such as of copper e.g. laminated onto and/or between sheet layers of a non-conductive substrate. The electronic circuit may be designated as a system in package electronic circuit.

The method comprises mounting one or more electronic components including a first electronic component and optionally a second electronic component on the circuit board. The one or more electronic components, such as the first electronic component and/or the second electronic component may be mounted to e.g. by being soldered, embedded in the circuit board, or bonded e.g. wire bonded or adhesive bonded to the circuit board. The method may comprise mounting a plurality of electronic components on the circuit board.

The one or more electronic components may include a power supply unit such as switch-mode power supply e.g. comprising a switch capacitor or an inductor, e.g. as the first electronic component. In other words, the first electronic component may be a power supply unit such as switch-mode power supply e.g. comprising a switch capacitor and/or an inductor.

The one or more electronic components may include a processing unit or chip, e.g. as the first or second electronic component. In other words, the first electronic component and/or the second electronic component may be a processing unit or chip.

The one or more electronic components may include a receiver such as a speaker, a microphone, a filter, an antenna e.g. a magnetic radio, a battery, a transceiver, and/or an interface. The one or more electronic components may comprise a third electrical component, such as a speaker, a microphone, a filter, an antenna e.g. a magnetic radio, a battery, a transceiver, and/or an interface. The second electronic component may be electrically and/or magnetically shielded. The third electronic component may be non-shielded.

The one or more electronic components may generate electromagnetic fields of different magnitudes and at different frequencies, thereby creating electromagnetic interference between the electronic components, the electromagnetic interference being more or less disturbing for other electronic components e.g. depending on the operating frequencies of the electronic components and the magnitude of the electromagnetic fields.

The first electronic component has a proximal surface and a distal surface and may have a first area A_EC_1, a first height H_EC_1, and a first width. The first electronic component may for example be a power supply generating a first electromagnetic field at a first frequency (or first frequency range) and of a first magnitude. The first electronic component may have a first position on the circuit board. The first position of the first electronic component may e.g. be varied depending on the first area, the first height, and the first width of the electronic component. The first position of the electronic component may be determined based on the distance to the neighbouring electronic components, the distance to the edge of the circuit board, and/or the height of the electronic components. For example, it may be advantageous to position an electronic component having the largest height in the centre of the circuit board, such as to minimize the height of the electronic circuit at the edges giving more flexibility regarding the size and dimensions of the electronic circuit. The first electronic component may comprise a proximal surface facing towards the circuit board, and a distal surface facing away from the circuit board and optionally towards the first insulation layer (proximal surface of the first insulation layer).

A distance between two neighbouring electronic components, e.g. a distance between the first electronic component and the second electronic component, may preferably be such that the first insulation layer and optionally even the first shielding layer may penetrate between the electronic components.

The method comprises applying a first insulation layer, e.g. outside, such as on the distal side of, the first electronic component and/or on the circuit board. In other words, the method comprises applying at first insulation layer on the distal side of the first electronic component, i.e. the first electronic component is arranged between the circuit board and the first insulation layer or at least a first area of the first insulation layer. Applying a first insulation layer outside the first electronic component may comprise applying the first insulation layer on the distal surface of the first electronic component. Applying a first insulation layer may comprise applying a first insulation layer outside a plurality of electronic components e.g. applying a portion of the first insulation layer on each electronic component individually or applying a first insulation layer on a plurality of electronic components such that the first insulation layer is substantially continuous on the plurality of electronic components. Applying a first insulation layer may comprise conformal coating of the first insulation layer. Conformal coating may provide a uniform first insulation layer on the electronic component(s), such as the first electronic component and/or on the second electronic component, and minimize the thickness of the first insulation layer that is needed to cover the electronic component(s).

The first insulation layer may contact or be substantially in contact with, e.g. adhering to, electronic component(s), e.g. the first electronic component and/or the second electronic component, for example such that the proximal surface (or at least a part) of the first insulation layer adheres to the distal surface of the first electronic component and/or the second electronic component. It may be advantageous that the first insulation layer adheres to the first electronic component and/or the second electronic component, such that substantially no air is trapped between the first insulation layer and at least the distal surface of the first electronic component and/or the second electronic component. This may further avoid that any moisture penetrates and collects between the first insulation layer and the electronic component(s), such as the first electronic component and/or the second electronic component, which may lead to damage or misfunction of the electronic component(s).

The first shielding layer may contact or be substantially in contact with, e.g. adhering to, the first insulation layer, for example such that the proximal surface (or at least a part) of the first shielding layer adheres to the distal surface of the first insulation layer. In the same way, it may be advantageous that the first shielding layer adheres to the first insulation layer, such that substantially no air is trapped between the first shielding layer and the first insulation layer. It is to be understood that further insulation layers, such as second insulation layer and/or third insulation layer, and/or one or more adhesive layers may be applied and/or arranged between the first insulation layer and the first shielding layer. In an exemplary method/electronic circuit, a second insulation layer of a second insulation material (optionally with a second viscosity different from such as smaller than the first viscosity) may be applied and/or arranged between the circuit board and the electronic component(s) and/or in gaps between neighbouring electronic components. Accordingly, the method may comprise applying a second insulation material to the circuit board and/or between electronic components. Applying a second insulation material to the circuit board and/or between electronic components may comprise underfilling the second insulation material. Further, it is to be understood that further shielding layers, such as second shielding layer and/or third shielding layer may be applied outside the first shielding layer, e.g. between the first shielding layer and the first protection layer.

The first insulation layer may be said to encapsulate or cover one or more of the electronic components, such as the first electronic component and/or the second electronic component, such that the electronic component(s) may be protected from the surrounding environment.

The first insulation layer may be an electrically non-conductive layer such that no electrical or galvanic contact may be established to the first electrical component, e.g. from the first shielding layer. Thus, the first insulation layer may be made of a first insulation material optionally comprising one or more polymers. The first insulation material may be an electrically non-conductive material.

The first insulation layer may insulate the first electronic component from the first shielding layer. In other words, the first insulation layer may prevent galvanic contact between the first electronic component and the first shielding layer.

The first insulation layer may have a first viscosity associated with the first insulation material (prior to curing) and/or a first thickness T_FIL_1 associated with the first electronic component. The first thickness T_FIL_1 may preferably be the thickness of the first insulation layer as the final product i.e. after the last processing step has been performed on the first insulation layer. The first viscosity may e.g. be in the range from 0.2 to 300 Pa·s, in the range from 0.5 to 175 Pa·s, in the range from 1 to 30 Pa·s, in the range from 1-20 Pa·s, or in the range from 3 to 10 Pa·s, when measured at a temperature of 20-25° C. In one or more exemplary methods and/or electronic circuits, the first viscosity of the first insulation material may be in the range from 80 Pa·s to 120 Pa·s, such as about 100 Pa·s. The first thickness may also be understood as a first distance from the proximal surface of the first insulation layer to the distal surface of the first insulation layer, e.g. to the proximal surface of the first shielding layer. The first insulation layer may have a second thickness associated with the second electronic component. The first thickness of the first insulation layer may be the same or different from, such as larger than or smaller than the second thickness of the first insulation layer. The first thickness T_FIL_1 of the first insulation layer may be defined as the maximal thickness of the first insulation layer i.e. the point or area where the first insulation layer is the thickest in the first area A_EC_1 of the first electronic component. The first insulation layer may comprise a first height H_FIL_1. The first height H_FIL_1 may be defined as the distance between the surface of the circuit board facing the proximal surface of the first insulation layer and the distal surface of the first insulation layer at the maximal point or area of the first insulation layer at the first area A_EC_1 of the first electronic component. The first height H_FIL_1 may substantially correspond to the first thickness T_FIL_1 added with the first height of the first electrical component H_EC_1. The second thickness T_FIL_2 of the first insulation layer may be defined as the maximal thickness of the first insulation layer i.e. the point or area where the first insulation layer is the thickest in the second area A_EC_2 of the second electronic component. The first insulation layer may comprise a second height H_FIL_2. The second height H_FIL_2 may be defined as the distance between the surface of the circuit board facing the proximal surface of the first insulation layer and the distal surface of the first insulation layer at the maximal point or area of the first insulation layer at the second area A_EC_2 of the second electronic component. The second height H_FIL_2 may substantially correspond to the second thickness T_FIL_2 added with the second height of the second electrical component H_EC_2.

The first viscosity and the first thickness may e.g. be chosen based on one or more of the distance or gap between the electronic components, the method of applying the first insulation layer, and the type of electronic component. For example, for a smaller distance between the electronic components, i.e. a smaller gap, the viscosity of the first insulation material may be lower than for a larger distance between the electronic components, i.e. a larger gap. This may allow the first insulation material to penetrate gaps between the electronic components. The gap between two neighbouring electronic components, e.g. between the first electronic component and the second electronic component may e.g. be in the range from 1 μm to 1 cm, in the range from 5 μm to 5 mm, in the range from 10 μm to 1 mm, in the range from 20 μm to 500 μm, in the range from 20 μm to 200 μm, in the range from 20 μm to 100 μm, in the range from 500 μm to 1 cm, or in the range from 1 mm to 5 mm. In one or more exemplary methods and/or electronic circuits, the gap between two neighbouring electronic components, e.g. between the first electronic component and the second electronic component may e.g. be in the range from 20 μm to 20 mm. The viscosity of the first insulation material may be proportional to the distance between the electronic components. A lower viscosity e.g. in the range from 1 to 20 Pa·s may be preferred for smaller gaps e.g. gaps smaller than 500 μm, e.g. to promote the flowing of the first insulation material into smaller gaps. A higher viscosity may be preferred e.g. to avoid that the first insulation material flows out of the circuit board or unintentionally covers portions of the circuit board, such as ground pad elements.

The first insulation layer may comprise a plurality of portions, e.g. a first portion and a second portion, separated from each other. The first portion of the first insulation layer may cover and insulate the first electronic component. The second portion of the first insulation layer may cover and insulate the second electronic component.

An adhesive layer or coating may be applied before applying the first insulation layer, e.g. for promoting adhesion of the first insulation layer. An adhesive layer or coating may be applied after applying the first insulation layer and before applying the first shielding layer, e.g. for promoting adhesion of the first shielding layer.

The first insulation layer may be made of a first insulation material, for example comprising, essentially consisting of, or be of a polymer material. The first insulation layer may be of a non-conductive material, e.g. a non-electrically conductive polymer material. Examples of first insulation materials may be Namics® U8443, Electrolube® UVCL, Elpeguard® SL 1367, Humiseal® UV40, and Humiseal® 1R32A-2. The first thickness T_FIL_1 of the first insulation layer may be in the range from 10 to 500 μm, in the range from 50 to 400 μm, in the range from 100 to 300 μm, or in the range from 100 to 200 μm. The second thickness T_FIL_2 of the first insulation layer may be in the range from 10 to 500 μm, in the range from 50 to 400 μm, in the range from 100 to 300 μm, or in the range from 100 to 200 μm.

The first insulation material may e.g. comprise and/or function as an underfill material having low viscosity, i.e. lower than 15 Pa·s, such as lower than 1 Pa·s. Thereby, the first insulation layer may penetrate around and below the first electronic component and/or the second electronic component.

The method comprises applying a first shielding layer, e.g. outside, such as on the distal side of, the first insulation layer and/or on the circuit board. In other words, the method comprises applying at first shielding layer, e.g. a first portion and/or a second portion, on the distal side of the first insulation layer, i.e. the first insulation layer (first area of the first insulation layer) is arranged between the first electronic component and the first shielding layer (first area of the first shielding layer). Applying a first shielding layer outside the first insulation layer may comprise applying the first shielding layer on the distal surface of the first insulation layer. Thus, the proximal surface of the first insulation layer faces towards the circuit board and the distal surface of the first insulation layer may be facing towards the first shielding layer (proximal surface of the first shielding layer). The first shielding layer has a proximal surface facing towards the circuit board and optionally facing the distal surface of the first insulation layer.

The first shielding layer may be an electrically conducting layer. Thus, the first shielding layer may be made of a first shielding material. The first shielding material may be an electrically conductive material. The conductivity of the first shielding layer may be in the range from 1 to 100 μΩ·cm.

The first shielding layer may shield electronic component(s), such as the first electronic component and/or the second electronic component, from electromagnetic radiation (act as a Faraday cage), optionally from other electronic components of the electronic circuit. In other words, the shielding layer may prevent electromagnetic radiation disturbing the electronic components. On the other hand, the first shielding layer may shield other electronic component(s) of the circuit board from electromagnetic radiation generated by the first electronic component and/or the second electronic component. The shielding provided by the first shielding layer may be in the range of 1-200 dB depending on the frequency or frequency range to shield. The first shielding layer may be made of a first shielding material being a conductive material, e.g. an electrically conductive polymer material. The first shielding material may be conductive polymer material, e.g. a conductive coating, e.g. based on inorganic or organic material, a conductive ink, a conductive micro-ink comprising micrometer-sized particles, or a conductive nano-ink comprising nanometer-sized particles. Examples of first shielding materials may be Genes′ink® Smart spray S-CS11101, Genes′ink® Smart′ink S-CS21303, Genes′ink® Smart′ink S-CS01520, Tatsuta® AE1244, Tatsuta® AE5000A5, Tatsuta® AE5000L, Tatsuta® AE5000ST, or Tatsuta® SF-PC5600.

The first shielding layer may have a first viscosity associated with the first shielding material and/or a first thickness associated with the first electronic component. The first viscosity of the first shielding material may (prior to curing) e.g. be in the range from 0.001 to 200 Pa·s, in the range from 0.01 to 100 Pa·s, in the range from 1 to 50 Pa·s, in the range from 1 to 30 Pa·s, in the range from 1 to 20 Pa·s, in the range from 3 to 10 Pa·s, in the range from 0.001 to 10 Pa·s, or in the range from 0.005 to 10 Pa·s, e.g. measured at a temperature of 20-25° C. The first thickness of the first shielding layer may also be understood as a first distance from the proximal surface of the first shielding layer to the distal surface of the first shielding layer. The first shielding layer may have a second thickness associated with the second electronic component. The first thickness of the first shielding layer may be the same or different from, such as larger than or smaller than the second thickness of the first shielding layer. The first thickness T_FSL_1 of the first shielding layer may be defined as the maximal thickness of the first shielding layer i.e. the point or area where the first shielding layer is the thickest at the first area A_EC_1 of the first electronic component. The first shielding layer may comprise a first height H_FSL_1. The first height H_FSL_1 may be defined as the distance between the surface of the circuit board facing the proximal surface of the first shielding layer and the distal surface of the first shielding layer at the maximal point or area of the first shielding layer at the first area A_EC_1. The first height H_FSL_1 may substantially correspond to the first thickness T_FSL_1, added to the first thickness T_FIL_1 and added with the first height of the first electrical component H_EC_1. The first thickness T_FSL_1 may preferably be the thickness of the first shielding layer as the final product i.e. after the last processing step has been performed on the first shielding layer. The second thickness T_FSL_2 of the first shielding layer may be defined as the maximal thickness of the first shielding layer i.e. the point or area where the first shielding layer is the thickest at the second area A_EC_2 of the second electronic component. The first shielding layer may comprise a second height H_FSL_2. The second height H_FSL_2 may be defined as the distance between the surface of the circuit board facing the proximal surface of the first shielding layer and the distal surface of the first shielding layer at the maximal point or area of the first shielding layer at the second area A_EC_2. The second height H_FSL_2 may substantially correspond to the second thickness T_FSL_2, added to the second thickness T_FIL_2 and added with the second height of the second electrical component H_EC_2. The second thickness T_FSL_2 may preferably be the thickness of the first shielding layer as the final product i.e. after the last processing step has been performed on the first shielding layer.

Properties of exemplary electronic circuits EC1-EC4 are outlined in table 1 below. The second electronic component of EC1-EC4 may be omitted.

TABLE 1
Properties of exemplary electronic circuits

| | EC1 | | EC2 | | EC3 | | EC4 | |
|---|---|---|---|---|---|---|---|---|
| A_EC_1 | 5-10 | mm² | 8-9 | mm² | 0.5-2 | mm² | 1-10 | mm² |
| H_EC_1 | 0.5-2 | mm | NA | | <1 | mm | >H_EC_2 | |
| A_EC_2 | 2-7 | mm² | 3-4 | mm² | 6-8 | mm² | 1-10 | mm² |
| H_EC_2 | 0.5-2 | mm | NA | | <1 | mm | <1 | mm |
| T_FIL_1 | 10-30 | μm | 20-30 | μm | 20-30 | μm | <T_FIL_2 | |
| T_FIL_2 | 35-60 | μm | 45-55 | μm | 30-40 | μm | >30 | μm |
| T_FSL_1 | 50-150 | μm | 80-120 | μm | 30-70 | μm | <120 | μm |

| | | | | | | | |
|---|---|---|---|---|---|---|---|
| T_FSL_2 | 150-250 | μm | 180-220 | μm | 60-70 | μm | >T_FSL_2 |

The first viscosity and the first thickness of the first shielding layer may e.g. be chosen based on one or more of the distance or the gap between the electronic components, the method of applying the first shielding layer, the type of electronic component, and properties of the first insulation layer. For example, for a smaller distance between the electronic components, i.e. a smaller gap, the viscosity of the first shielding material may be lower than for a larger distance between the electronic components, i.e. a larger gap. This may allow the first shielding material to penetrate between the electronic components. The viscosity of the first shielding material may be proportional to the distance between the electronic components.

The first thickness of the first shielding layer may depend on a frequency of the generated electromagnetic interference by the first electronic component to be shielded. The frequency to be shielded may be determined based on the operating frequency of one or more electronic components of the electronic circuit. For example, an antenna may operate at a frequency that matches a frequency of the generated electromagnetic interference of an electronic component, such as the first electronic component. In that case it may be important to shield that specific frequency such that the antenna may operate without being disturbed. Thus, depending on the frequency of the generated electromagnetic interference to be shielded, the first thickness of the first shielding layer may be varied. The shielded frequency is dependent on the thickness of the first shielding layer. For example, in order to shield an electromagnetic interference having a frequency about 1 MHz, the first thickness, T_FSL_1, of the first shielding layer may be in the range from 1 μm to 500 μm, in the range from 10 μm to 300 μm, in the range from 20 μm to 200 μm, in the range from 30 μm to 100 μm, or in the range from 50 μm to 80 μm.

The first shielding material may be selected depending on the frequency or frequency range to be shielded. The frequency range to be shielded may e.g. be in the range from 0.1 kHz to 10 GHz or in the range from 1 MHz-1 GHz.

The first shielding material may comprise one or more metals including a first metal and/or a second metal. The one or more metals may be selected from copper, silver, gold, platinum, and nickel. The first shielding material may comprise an alloy. The first shielding material may be or comprise a conducive polymer. The first shielding material may comprise metal particulates, such as μm metal particulates and/or nm metal particulates. The metal particulates may be or comprise copper particulates, silver particulates, gold particulates, zinc particulates, and/or nickel particulates. The metal particulates may have a concentration in the first shielding material in the range from 1 to 100 wt %, such as in the range from 5 to 30 wt %,

The first shielding layer may comprise a plurality of portions, e.g. a first portion and a second portion, separated from each other. The first portion of the first shielding layer may cover and shield the first electronic component. The second portion of the first shielding layer may cover and insulate the second electronic component.

In one or more exemplary methods, applying the first shielding layer outside the first insulation layer comprises contacting the first shielding layer, such as the first portion and/or the second portion of the first shielding layer, to a ground connection, such as to one or more ground pad elements, e.g. of a ground pad ring. The ground connection may e.g. be a ground connection of the circuit board, a ground connection through the first electronic component being connected to a ground connection of the circuit board, a ground pad ring e.g. at least partly encircling the first electronic component. The ground connection may comprise one or more ground pad elements.

The ground pad ring may be a continuous ring such that the ground pad ring is whole. The ground pad ring may be formed by a number of ground pad elements arranged along a closed curve, e.g. encircling the first electronic component and/or the second electronic component. A ground pad ring having a continuous ring may provide greater flexibility for the grounding of the first shielding layer. The continuous ring of the ground pad ring may have a width in the range from 1 μm to 100 μm, preferably between 5-50 μm, more preferably between 10-50 μm.

In one or more exemplary methods/electronic circuits, the first shielding layer is not contacted to a ground connection but is outside the first insulation layer without being in contact with a ground connection.

In one or more exemplary methods, applying a first insulation layer outside the first electronic component comprises moulding first insulation material on the first electronic component, e.g. on distal surface of the first electronic component. Moulding first insulation material may comprise to provide a mould around the first electronic component e.g. to delimit the area to mould, and then applying first insulation material on the first electronic component, e.g. by injecting first insulation material into the space/cavity between the mould and the first electronic component/circuit board.

In one or more exemplary methods, applying a first insulation layer outside the first electronic component comprises spraying first insulation material on the first electronic component. Applying a first insulation layer outside the first electronic component may comprise masking, e.g. by arranging a masking element, e.g. prior to spraying first insulation material on the first electronic component. Thus, application of first insulation material to selected areas is provided for e.g. preventing ground connection from being covered with first insulation material.

In one or more exemplary methods, applying a first insulation layer outside the first electronic component comprises curing the first insulation material. Curing the first insulation material may comprise heat-curing, e.g. low-temperature curing, moisture-curing, UV-curing, infrared light curing, near infrared light curing, or photonic curing. The curing temperature may e.g. be in the range from 60° C. to 500° C., in the range from 60° C. to 400° C., in the range from 80° C. to 300° C., or in the range from 50° C. to 200° C. The curing of the first insulation material may comprise evaporating part of the first insulation material. The composition of the first insulation material may therefore be different after the first insulation material have been cured. The first thickness T_FIL_1 may also be different before and after curing e.g. T_FIL_1 is thinner after curing than before. The curing of the first insulation material may comprise polymerization reaction due to the UV light source. Moreover, for UV-curable materials, a secondary moisture-curing mechanism may be applied, e.g. for shadowed areas.

In one or more exemplary methods, applying a first insulation layer outside the first electronic component comprises jetting first insulation material on the first electronic component, e.g. on distal surface of the first electronic component. In one or more exemplary methods, jetting first insulation material on the first electronic component may be combined with masking prior to jetting first insulation material, e.g. by arranging a masking element. Thus, in one or more exemplary methods, applying a first insulation layer outside the first electronic component comprises applying a masking before jetting the first insulation material. Jetting first insulation material may comprise printing first insulation material on the first electronic component and/or circuit board. Jetting the first insulation material may allow for a more automized and accurate application of the first insulation layer, e.g. by removing human steps in the manufacturing of the electronic circuit. This may provide a higher uniformity of the layers applied e.g. the thickness of the layers, and in turn provide more reliable layers. Further, introduction of potential human/operator-related contamination on the boards-to-be-coated can be reduced and/or prevented. Both the applying of the first insulation layer and the applying of the first shielding layer may be achieved by jetting, which allows the use of the same machine for both steps. By using the same machine, the number of fabrication steps of the electronic circuit may be reduced, whereby an easier and faster fabrication process may be achieved. Jetting first insulation material may e.g. comprise one or more of screen printing, inkjet, and aerosol printing. The jetting may e.g. be tilt jetting e.g. to provide a more uniform layer.

In one or more exemplary methods, applying a first insulation layer outside the first electronic component comprises covering the first electronic component with first insulation material, optionally followed by curing the first insulation material.

In one or more exemplary methods, applying a first shielding layer outside the first electronic component comprises curing the first shielding material.

Curing the first shielding material may comprise heat-curing, e.g. low-temperature curing, moisture curing, UV-curing, infrared light curing, near infrared light curing, or photonic curing. The curing temperature may e.g. be in the range from 60° C. to 500° C., in the range from 60° C. to 400° C., in the range from 80° C. to 300° C., or in the range from 50° C. to 200° C. The curing of the first shielding material may comprise evaporating part of the first shielding material. The composition of the first shielding material may therefore be different after the first shielding material has been cured. After the curing, the metal particulates of the first shielding layer may e.g. be more concentrated than before curing, providing a higher density of metal particulates, whereby a higher conductivity may be achieved. The first thickness T_FSL_1 may also be different before and after curing e.g. T_FSL_1 is thinner after curing than before curing. The curing of the first shielding material may comprise polymerization reaction due to the UV light source. Moreover, for UV-curable materials, a secondary moisture-curing mechanism may be applied, e.g. for shadowed areas.

In one or more exemplary methods, applying a first shielding layer outside the first electronic component comprises moulding first shielding material on the first electronic component.

In one or more exemplary methods, applying a first shielding layer outside the first electronic component comprises spraying first shielding material on the first electronic component. Spraying first shielding material on the first electronic component may be advantageous for low-viscosity material

In one or more exemplary methods, applying a first shielding layer outside the first electronic component comprises jetting first shielding material on the first electronic component.

In one or more exemplary methods, applying a first shielding layer outside the first electronic component comprises applying a masking before jetting, spraying or otherwise applying the first shielding material. Thereby, improved control of the application of first shielding material may be provided.

Jetting first shielding material may e.g. comprise inkjet and/or aerosol printing. The jetting may e.g. be tilt jetting e.g. to provide a more uniform layer.

In one or more exemplary methods, applying a first shielding layer outside the first electronic component comprises covering the first electronic component with first shielding material.

The method may comprise applying a first protection layer outside the first shielding layer. The first protection layer may be an environment protecting layer protecting the first shielding layer, the first insulation layer, the first electrical component, and more generally the electronic circuit (or at least parts thereof) and the audio device e.g. from the surrounding environment such as climate, e.g. climate-related stressors (moisture, temperature), climate-related contaminants (e.g. dust), and/or human, e.g. human-related contaminants (human secretion products). The first protection layer may fully cover the first insulation layer and/or the first shielding layer.

The first protection layer may be made of a first protection material. The first protection material may be the same as the first insulation material. The first protection material may comprise or essentially consist of a similar or the same material as the first insulation material of the first insulation layer. This may be an advantage with regards to the adhesion between the first protection layer, the first shielding layer, and the first insulation layer. Further, use of the same material for the first insulation layer and the first protection layer simplifies the manufacture of the electronic circuit. The first protection material may alternatively be different from the first insulation material. The first protection layer may protect the first shielding layer from corroding. This may avoid e.g. an unwanted connection between one or more electrical components. An unwanted connection may for example be a connection between a battery having a first voltage and an electrical component having a second voltage different from the first voltage, whereby the battery may be drained or damaged and/or the electrical component may be damaged.

An audio device is disclosed. The audio device comprises a housing and an electronic circuit accommodated in the housing, the electronic circuit comprising a circuit board and one or more electronic components including a first electronic component mounted on the circuit board, the electronic circuit comprising a first insulation layer and a first shielding layer covering the first electronic component. The first insulation layer is arranged between the first electronic component and the first shielding layer. The first insulation layer has a thickness, e.g. a mean thickness and/or a first thickness less than 500 μm.

The audio device may be a hearing device such as a hearable or a hearing aid, comprising a processor configured to compensate for a hearing loss of a user. The audio device may be of the behind-the-ear (BTE) type, in-the-ear (ITE) type, in-the-canal (ITC) type, receiver-in-canal (RIC) type or receiver-in-the-ear (RITE) type. The hearing aid may be a binaural hearing aid. The first insulation layer and/or the first protection layer may insulate and protect the electronic circuit and in turn the audio device from the environment that the audio device is exposed to. For example, when the audio device is worn by a user the audio device may be exposed to sweat and cerumen from the user and weather conditions such as humidity, heat, and dust, which may be desirable to be insulated and protected from.

In one or more exemplary methods/electronic circuits/audio devices, the one or more electronic components comprises a second electronic component. The method may comprise applying the first insulation layer on the second electronic component.

In one or more exemplary electronic circuits/audio devices, the one or more electronic components comprise a second electronic component mounted on the circuit board. The first insulation layer and/or the first shielding layer may cover the second electronic component.

In one or more exemplary electronic circuits/audio devices, the electronic circuit comprises a first protection layer outside the first shielding layer. The first protection layer may fully or at least partially cover the first shielding layer. In one or more exemplary electronic circuits/audio devices, the circuit board comprises a ground connection contacting the first shielding layer. In one or more exemplary electronic circuits/audio devices, the first shielding layer, or at least a first portion and/or a second portion of the first shielding layer, is insulated from the ground connection of the circuit board.

In one or more exemplary electronic circuits, the first insulation layer may substantially cover the circuit board combined with the first shielding layer covering the electronic components and the first protection layer covering the first shielding layer.

It is to be understood that a description of a feature in relation to method(s) is also applicable to the corresponding feature in electronic circuit/audio device.

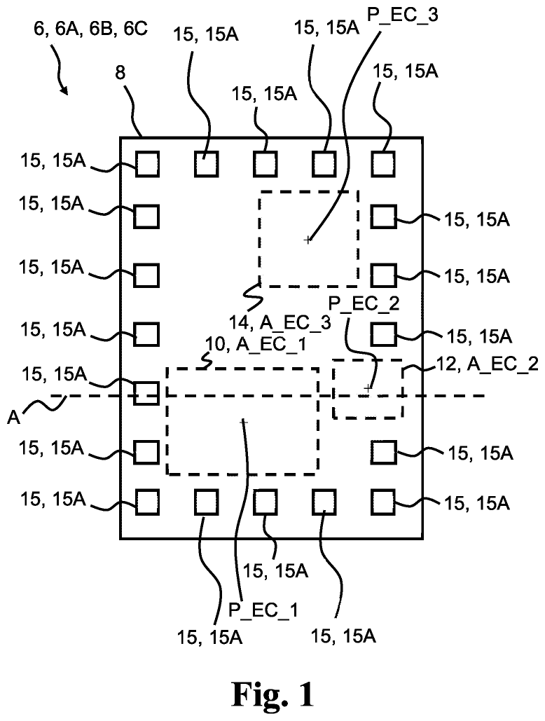

FIG. 1 shows a first or distal view of parts of exemplary electronic circuits. The electronic circuit 6, 6A, 6B, 6C comprises a circuit board 8 and one or more electronic components including a first electronic component 10 having a first area A_EC_1. The first electronic component 10 is mounted on the circuit board 8 at a first position P_EC_1. The first electronic component 10 may be a power supply module. The electronic circuit 6 optionally comprises a second electronic component 12 having a second area A_EC_2. The second electronic component 12 is mounted on the circuit board 8 at a second position P_EC_2. The electronic circuit 6 optionally comprises a third electronic component 14 having a third area A_EC_3. The third electronic component 14 is mounted on the circuit board 8 at a third position P_EC_3. The third electronic component 14 may be an antenna. The circuit board 8 comprises a ground connection 15, the ground connection 15 comprising one or more ground pad elements 15A exposed on the circuit board. The ground pad elements 15A are connected to a common ground of the circuit board 8.

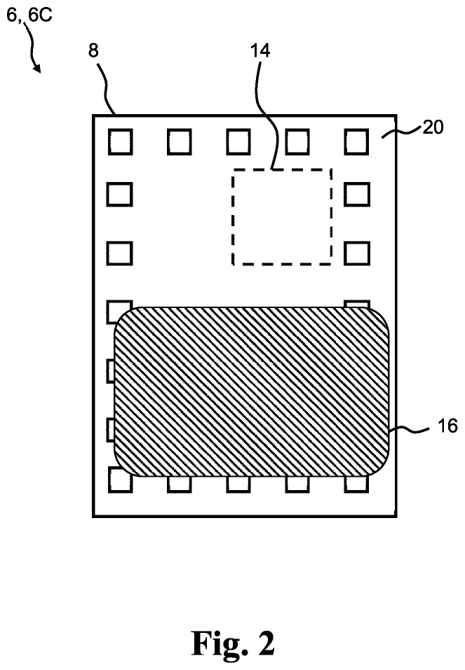

FIG. 2 shows a first view or distal view of parts of exemplary electronic circuits. The electronic circuit 6, 6C comprises a first insulation layer 16 covering the first electronic component 10 (first area A_EC_1) and optionally the second electronic component 12 (second area A_EC_2).

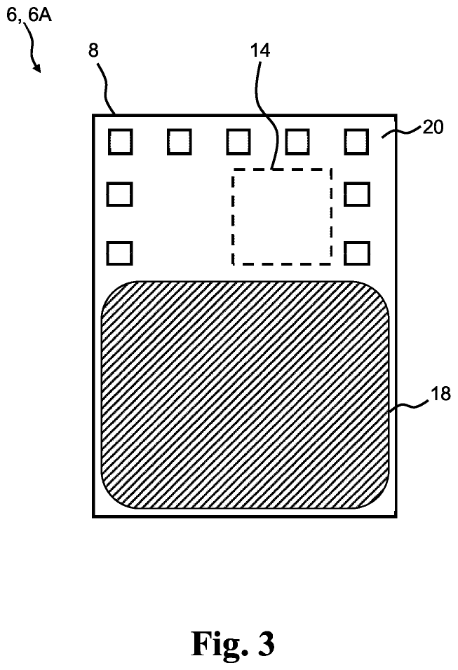

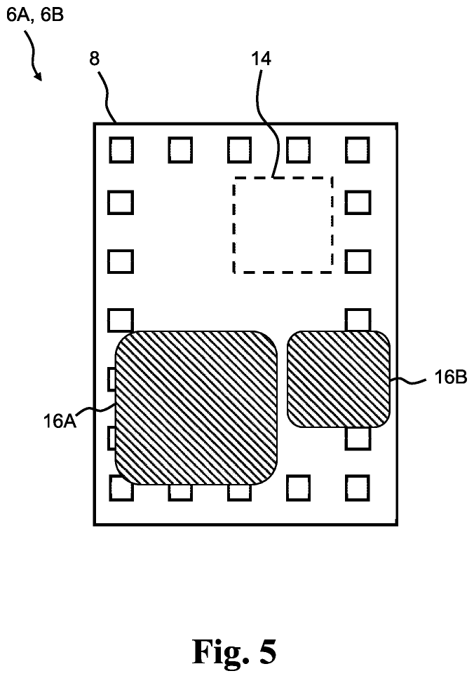

FIG. 3 shows a first view or distal view of parts of exemplary electronic circuits. The electronic circuit 6, 6A comprises a first shielding layer 18 outside and covering the first insulation layer 16, 16A, 16B, see FIG. 2 and FIG. 5. The first shielding layer 18 covers and shields the first electronic component 10 (first area A_EC_1) and optionally the second electronic component 12 (second area A_EC_2). Further, the first shielding layer 18 is in electrical (galvanic) contact with the ground connection 15 via one or more ground pad elements. The first shielding layer 18 may have first electromagnetic properties in the first area of the first electronic component 10 and may be configured to shield a first electromagnetic interference of the first electronic component 10, e.g. to shield in a first frequency range such as in a frequency range used by another electronic component of the electronic circuit. The first shielding layer 18 may have second electromagnetic properties in the second area of the second electronic component 12 and may be configured to shield a second electromagnetic interference of the second electronic component 12, e.g. to shield in a second frequency range such as in a frequency range used by another electronic component of the electronic circuit.

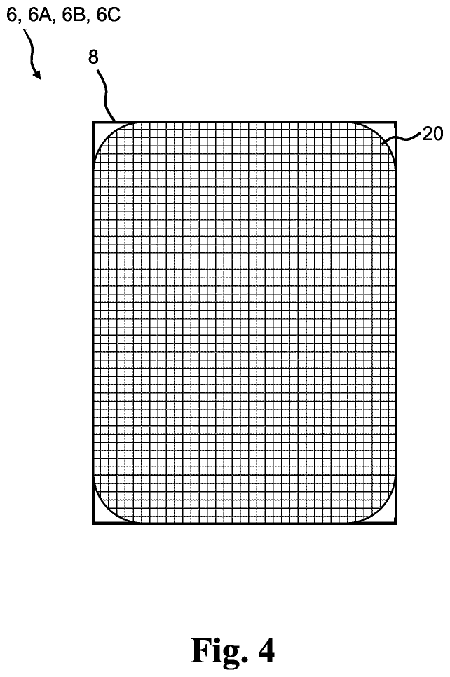

FIG. 4 shows a first or distal view of parts of exemplary electronic circuits. The electronic circuit 6, 6A, 6B, 6C optionally comprises a first protection layer 20 outside and covering the first shielding layer 18, 18A, 18B.

FIG. 5 shows a first view or distal view of parts of exemplary electronic circuits. The first insulation layer is separated into at least a first portion 16A and a second portion 16B, e.g. to provide increased design flexibility when designing the electronic circuit. Accordingly, the electronic circuit 6A, 6B comprises a first portion 16A of first insulation layer and a second portion 16B of first insulation layer. The first portion 16A of first insulation layer is outside and covering the first electronic component 10. The second portion 16B of first insulation layer is outside and covering the second electronic component 12.

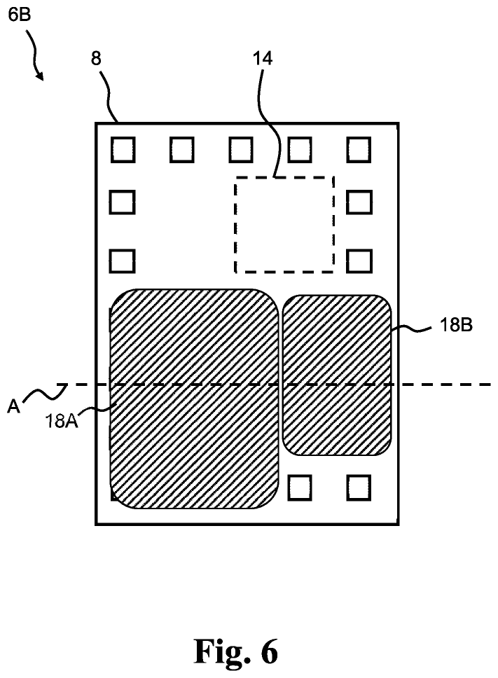

FIG. 6 shows a first view or distal view of parts of exemplary electronic circuits. The first shielding layer is separated into at least a first portion 18A and a second portion 18B, e.g. to provide increased design flexibility when designing the electronic circuit. Accordingly, the electronic circuit 6B comprises a first portion 18A of first shielding layer outside and covering the first portion 16A of the first insulation layer, see FIG. 5. The first portion 18A of the first shielding layer covers and shields the first electronic component 10. Further, the electronic circuit 6B optionally comprises a second portion 18B of first shielding layer outside and covering the second portion 16B of the first insulation layer, see FIG. 5. The second portion 18B of the first shielding layer covers and shields the second electronic component 12. The first portion 18A of the first shielding layer and the second portion 18B of the first shielding layer may have the same of different properties, such as thickness and/or shielding material. The first portion 18A may have first electromagnetic properties configured to shield a first electromagnetic interference of the first electronic component, e.g. to shield in a first frequency range such as in a frequency range used by another electronic component of the electronic circuit. The second portion 18A may have second electromagnetic properties configured to shield a second electromagnetic interference of the second electronic component, e.g. to shield in a second frequency range such as in a frequency range used by another electronic component of the electronic circuit. The first portion 18A and/or the second portion may contact one or more ground pad elements of the circuit board, respectively. In one or more exemplary electronic circuits, the first portion of the first shielding layer may be insulated from the ground connection of the circuit board. In one or more exemplary electronic circuits, the second portion of the first shielding layer may be insulated from the ground connection of the circuit board.

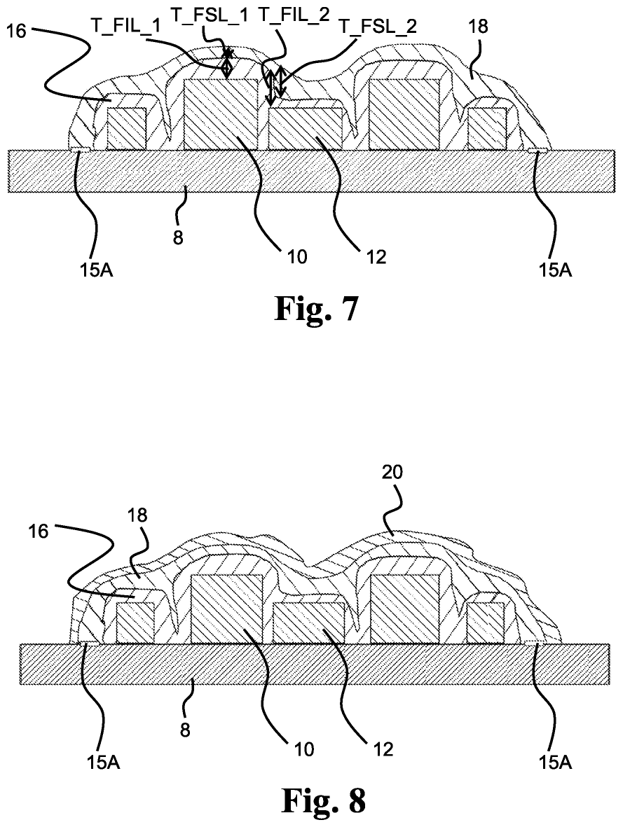

FIG. 7 and FIG. 8 show cross-sections of different exemplary electronic circuits. The first thickness T_FIL_1 of the first insulation layer 16 is smaller than the second thickness T_FIL_2 of the first insulation layer 16. The first thickness T_FSL_1 of the first shielding layer 18 is smaller than the second thickness T_FSL_2 of the first shielding layer 18.

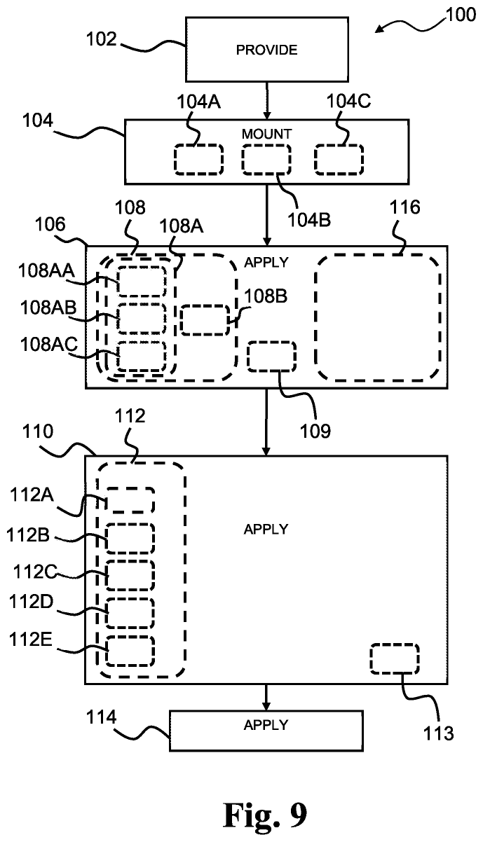

FIG. 9 is a flow diagram of an exemplary method. The method 100 of manufacturing an electronic circuit of an audio device comprises providing 102 a circuit board; mounting 104 one or more electronic components including a first electronic component on the circuit board; applying 106 a first insulation layer; and applying 110 a first shielding layer. In method 100, applying 106 a first insulation layer comprises applying 108 the first insulation layer outside, e.g. on a distal side of, the first electronic component. Applying 108 the first insulation layer outside the first electronic component may comprise one or more of moulding 108AA first insulation material on the first electronic component, spraying 108AB first insulation material on the first electronic component, and jetting first insulation material on the first electronic component, e.g. as part of optionally covering 108A the first electronic component with first insulation material. In method 100, applying 108 a first insulation layer outside the first electronic component optionally comprises applying 108B a masking optionally before jetting 108AC and/or spraying 108AB the first insulation material. The first insulation layer is made of a first insulation material comprising one or more polymers. In method 100, applying 106 a first insulation layer optionally comprises curing 109 the first insulation layer.

In the method 100, applying 110 a first shielding layer optionally comprises applying 112 a first shielding layer outside, e.g. on a distal side of, the first insulation layer. Applying 110 a first shielding layer optionally comprises contacting 112A the first shielding layer to a ground connection, e.g. as part of applying 112 a first shielding layer outside, e.g. on a distal side of, the first insulation layer.

Applying 112 the first shielding layer outside the first insulation layer may comprise one or more of moulding 112B first shielding material on the first insulation layer, spraying 112C first shielding material on the first insulation layer, and jetting 112D first shielding material on the first insulation layer, e.g. as part of optionally covering the first insulation layer with first shielding material. In method 100, applying 112 a first shielding layer outside the first insulation layer optionally comprises applying 112E a masking optionally before jetting 112D and/or spraying 112C the first shielding material. The first shielding layer is made of a first shielding material comprising metal particulates, such as one or more of copper particulates, silver particulates, gold particulates, zinc particulates, platinum particulates, and/or nickel particulates. In method 100, applying 110 a first shielding layer optionally comprises curing 113 the first shielding layer.

The method 100 comprises applying 114 a first protection layer outside the first shielding layer. Further, the one or more electronic components optionally comprises a second electronic component, and the method 100 may comprise applying 116 the first insulation layer outside or on the second electronic component.

FIG. 10 shows a cross-sectional view along dotted line A of electronic circuit 6A. The first portion 16A of the first insulation layer covering the first electronic component 10 has a first thickness T_FIL_1 in the range from 10 μm to 500 μm. The second portion 16B of the first insulation layer covering the second electronic component 12 has a second thickness T_FIL_2 in the range from 10 μm to 500 μm. The first shielding layer 18 comprises metallic particles and contacts ground pad element 15A. The first shielding layer 18 covers the first portion 16A and the second portion 16B of the first insulation layer and therefore also the first electronic component 10 and the second electronic component 12. The first shielding layer has a first thickness T_FSL_1 (maximum thickness in the first area of the first electronic component) in the range from 10 μm to 500 μm and a second thickness T_FSL_2 (maximum thickness in the second area of the second electronic component) in the range from 10 μm to 500 μm. The first thickness T_FSL_1 is different from the second thickness T_FSL_2 and configured to shield a first electromagnetic field from the first electronic component 10. The second thickness T_FSL_2 is configured to shield a second electromagnetic field from the second electronic component 12.

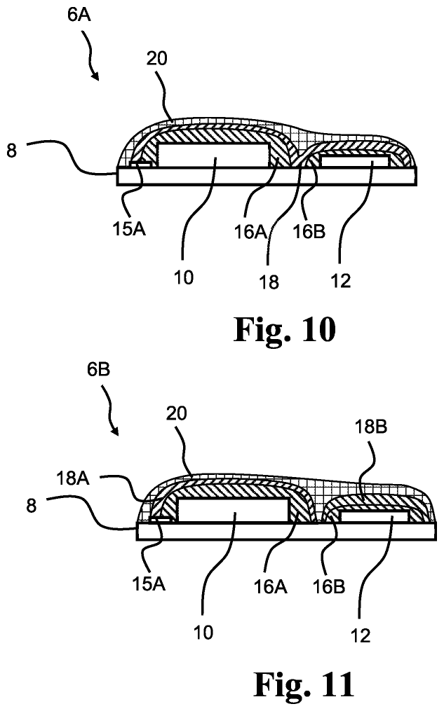

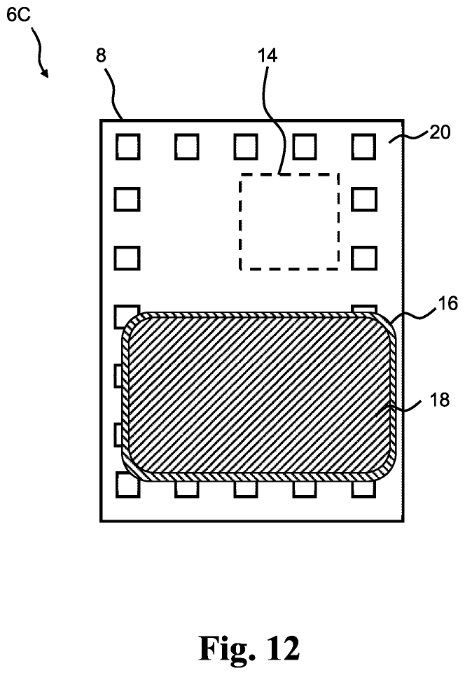

FIG. 11 shows a cross-sectional view along dotted line A of electronic circuit 6B. The first portion 16A of the first insulation layer covering the first electronic component 10 has a first thickness T_FIL_1 in the range from 10 μm to 500 μm. The second portion 16B of the first insulation layer covering the second electronic component 12 has a second thickness T_FIL_2 in the range from 10 μm to 500 μm. The first shielding layer comprises metallic particles and both the first portion 18A and the second portion 18B contact at least one respective ground pad element 15A. The first portion 18A and/or the second portion 18B may be insulated from the ground connection, i.e. be floating. The first portion 18A of the first shielding layer 18 covers the first portion 16A of the first insulation layer and therefore also the first electronic component 10. The second portion 18B of the first shielding layer 18 covers the second portion 16B of the first insulation layer and therefore also the second electronic component 12. The first portion 18A of the first shielding layer has a first thickness T_FSL_1 (maximum thickness in the first area of the first electronic component) in the range from 10 μm to 500 μm. The second portion 18B of the first shielding layer has a second thickness T_FSL_2 (maximum thickness in the second area of the second electronic component) in the range from 10 μm to 500 μm. The first thickness T_FSL_1 is different from the second thickness T_FSL_2 and configured to shield a first electromagnetic field from the first electronic component 10. The second thickness T_FSL_2 is configured to shield a second electromagnetic field from the second electronic component 12.

FIG. 12 shows a first view or distal view of parts of an exemplary electronic circuit. The electronic circuit 6C comprises a first shielding layer 18 outside and partly covering the first insulation layer 16. The first shielding layer 18 covers and shields the first electronic component 10 (first area A_EC_1) and optionally the second electronic component 12 (second area A_EC_2). Further, the first shielding layer 18 is insulated from the ground connection by the first insulation layer.

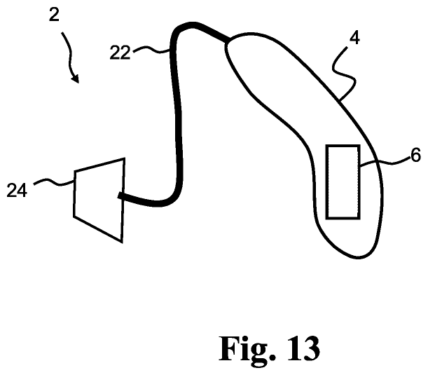

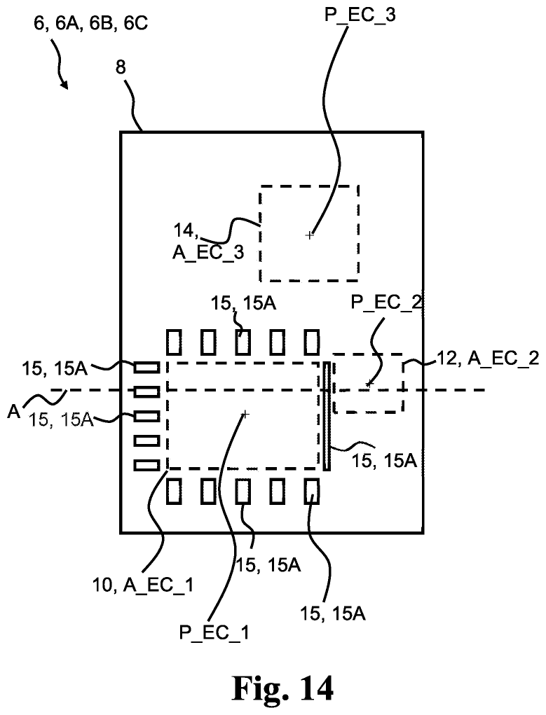

FIG. 13 shows an exemplary audio device 2. The audio device 2 comprises a housing 4 comprising an electronic circuit 6. The housing 4 being connected to an ear part 24 by a tubular member 22. The ear part 24 is configured to be positioned in an ear of a user of the audio device 2. The housing 4 is configured to be positioned behind the ear of a user. The tubular member 22 is configured to connect the housing 4 and thereby the electronic circuit 6 to the ear part 24 e.g. by being positioned above or beneath the ear of the user.

The first insulation layer 16 and/or the first protection layer 20 may insulate and protect the electronic circuit 6 and in turn the audio device 2 from the environment that the audio device 2 is exposed to. For example, when the audio device 2 is worn by a user the audio device 2 may be exposed e.g. to sweat and cerumen from the user and weather conditions such as humidity, heat, and dust, which may be desirable to be insulated and protected from.

In other exemplary audio devices (not shown) such as an in-the-ear (ITE) type or in-the-canal (ITC), the housing 4 may be an ear part 24, such that the housing 4 and the ear part 24 are in one piece positioned in the ear of the user. The ear part 24 may thereby be the audio device 2.

FIG. 14 shows a first or distal view of parts of exemplary electronic circuits with an alternative ground connection. The ground connection 15 is arranged around the first electronic component 10 and comprising one or more ground pad elements 15A exposed on the circuit board. The ground pad elements 15A are connected to a common ground of the circuit board 8.

Exemplary methods, audio devices, and electronic circuits) according to the disclosure are set out in the following items:

Item 1. A method of manufacturing an electronic circuit of an audio device, the method comprising:

providing a circuit board;

mounting one or more electronic components including a first electronic component on the circuit board;

applying a first insulation layer outside the first electronic component; and

applying a first shielding layer outside the first insulation layer.

Item 2. Method according to item 1, wherein applying the first shielding layer outside the first insulation layer comprises contacting the first shielding layer to a ground connection.
Item 3. Method according to any one of items 1-2, wherein applying a first insulation layer outside the first electronic component comprises moulding first insulation material on the first electronic component.
Item 4. Method according to any one of items 1-3, wherein applying a first insulation layer outside the first electronic component comprises spraying first insulation material on the first electronic component.
Item 5. Method according to any one of items 1-4, wherein applying a first insulation layer outside the first electronic component comprises jetting first insulation material on the first electronic component.
Item 6. Method according to any one of items 5, wherein applying a first insulation layer outside the first electronic component comprises applying a masking before jetting the first insulation material.
Item 7. Method according to any one of items 1-6, wherein applying a first insulation layer outside the first electronic component comprises covering the first electronic component with first insulation material.
Item 8. Method according to any one of items 1-7, the method comprising applying a first protection layer outside the first shielding layer.
Item 9. Method according to any one of items 1-8, wherein the first insulation layer is made of a first insulation material comprising one or more polymers.
Item 10. Method according to any one of items 1-9, wherein the first shielding layer is made of a first shielding material comprising metal particulates, such as copper particulates, silver particulates, zinc particulates, and/or nickel particulates.
Item 11. Method according to any one of items 1-10, wherein the one or more electronic components comprises a second electronic component, the method comprising applying the first insulation layer on the second electronic component.
Item 12. Audio device comprising a housing and an electronic circuit accommodated in the housing, the electronic circuit comprising a circuit board and one or more electronic components including a first electronic component mounted on the circuit board, the electronic circuit comprising a first insulation layer and a first shielding layer covering the first electronic component, the first insulation layer being arranged between the first electronic component and the first shielding layer, wherein the first insulation layer has a thickness less than 500 μm.
Item 13. Audio device according to item 12, wherein the one or more electronic components comprise a second electronic component mounted on the circuit board, the first insulation layer and the first shielding layer covering the second electronic component.
Item 14. Audio device according to any one of items 12-13, wherein the electronic circuit comprises a first protection layer outside the first shielding layer.
Item 15. Audio device according to any one of items 12-14, wherein the circuit board comprises a ground connection contacting the first shielding layer.
Item 16. Audio device according to any one of items 12-15, wherein the first electronic component comprises a ground connection contacting the first shielding layer.
Item 17. An electronic circuit for an audio device, the electronic circuit comprising a circuit board and one or more electronic components including a first electronic component mounted on the circuit board, the electronic circuit comprising a first insulation layer and a first shielding layer covering the first electronic component, the first insulation layer arranged between the first electronic component and the first shielding layer, wherein the first insulation layer has a thickness less than 500 μm.

The use of the terms “first”, “second”, “third” and “fourth”, “primary”, “secondary”, “tertiary” etc. does not imply any particular order, but are included to identify individual elements. Moreover, the use of the terms “first”, “second”, “third” and “fourth”, “primary”, “secondary”, “tertiary” etc. does not denote any order or importance, but rather the terms “first”, “second”, “third” and “fourth”, “primary”, “secondary”, “tertiary” etc. are used to distinguish one element from another. Note that the words “first”, “second”, “third” and “fourth”, “primary”, “secondary”, “tertiary” etc. are used here and elsewhere for labelling purposes only and are not intended to denote any specific spatial or temporal ordering.

Furthermore, the labelling of a first element does not imply the presence of a second element and vice versa.

It may be appreciated that FIGS. 1-14 comprise some modules or operations which are illustrated with a solid line and some modules or operations which are illustrated with a dashed line. The modules or operations which are comprised in a solid line are modules or operations which are comprised in the broadest example embodiment. The modules or operations which are comprised in a dashed line are example embodiments which may be comprised in, or a part of, or are further modules or operations which may be taken in addition to the modules or operations of the solid line example embodiments. It should be appreciated that these operations need not be performed in order presented. Furthermore, it should be appreciated that not all of the operations need to be performed. The exemplary operations may be performed in any order and in any combination.

It is to be noted that the word “comprising” does not necessarily exclude the presence of other elements or steps than those listed.

It is to be noted that the words “a” or “an” preceding an element do not exclude the presence of a plurality of such elements.

It should further be noted that any reference signs do not limit the scope of the claims, that the exemplary embodiments may be implemented at least in part by means of both hardware and software, and that several “means”, “units” or “devices” may be represented by the same item of hardware.

The various exemplary methods, devices, and systems described herein are described in the general context of method steps processes, which may be implemented in one aspect by a computer program product, embodied in a computer-readable medium, including computer-executable instructions, such as program code, executed by computers in networked environments. A computer-readable medium may include removable and non-removable storage devices including, but not limited to, Read Only Memory (ROM), Random Access Memory (RAM), compact discs (CDs), digital versatile discs (DVD), etc. Generally, program modules may include routines, programs, objects, components, data structures, etc. that perform specified tasks or implement specific abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps or processes.

Although features have been shown and described, it will be understood that they are not intended to limit the claimed invention, and it will be made obvious to those skilled in the art that various changes and modifications may be made without departing from the spirit and scope of the claimed invention. The specification and drawings are, accordingly to be regarded in an illustrative rather than restrictive sense. The claimed invention is intended to cover all alternatives, modifications, and equivalents.

### LIST OF REFERENCES

2 audio device
4 housing
6 electronic circuit
8 circuit board
10 first electronic component, power supply circuitry
12 second electronic component
14 third electronic component
15 ground connection
15A ground pad element
16 first insulation layer
16A first portion of first insulation layer
16B second portion of first insulation layer
18 first shielding layer
18A first portion of first shielding layer
18B second portion of first shielding layer
20 first protection layer
22 tubular member
24 ear part
100 method of manufacturing an electronic circuit of an audio device
102 providing a circuit board
104 mounting one or more electronic components on the circuit board
104A mounting a first electronic component on the circuit board
104B mounting a second electronic component on the circuit board
104C mounting a third electronic component on the circuit board
106 applying a first insulation layer
108 applying a first insulation layer outside the first electronic component
108A covering the first electronic component with the first insulation material.
108AA moulding first insulation material on the first electronic component.
108AB spraying first insulation material on the first electronic component
108AC jetting first insulation material on the first electronic component
108B applying a masking
109 curing the first insulation layer
110 applying a first shielding layer
112 applying a first shielding layer outside the first insulation layer
112A contacting the first shielding layer to a ground connection
112B moulding first shielding material on the first insulation layer
112C spraying first shielding material on the first insulation layer
112D jetting first shielding material on the first insulation layer
112E applying a masking
113 curing the first shielding layer
114 applying a first protection layer outside the first shielding layer.
116 applying the first insulation layer outside the second electronic component.
A_EC_1 first area of first electronic component
A_EC_2 second area of second electronic component
A_EC_3 third area of third electronic component
P_EC_1 first position of first electronic component
P_EC_2 second position of second electronic component
P_EC_3 third position of third electronic component
T_FIL_1 first thickness of the first insulation layer
T_FIL_2 second thickness of the first insulation layer
T_FSL_1 first thickness of the first shielding layer
T_FSL_2 second thickness of the first shielding layer

1. A method of manufacturing an electronic circuit of an audio device, the method comprising:
providing a circuit board;
mounting one or more electronic components including a first electronic component on the circuit board;
applying a first insulation layer outside the first electronic component; and
applying a first shielding layer outside the first insulation layer;
wherein the first insulation layer is made of a first insulation material comprising one or more polymers, and wherein the applying the first insulation layer outside the first electronic component comprises jetting or spraying the first insulation material towards the first electronic component.

2. The method according to claim 1, wherein the applying the first shielding layer outside the first insulation layer comprises coupling the first shielding layer to a ground connection.

3. The method according to claim 1, wherein the applying the first insulation layer outside the first electronic component also comprises performing moulding.

4. The method according to claim 1, wherein the first insulation material is jetted, and the method further comprises spraying additional first insulation material.

5. The method according to claim 1, wherein the first insulation material is sprayed, and the method further comprises jetting additional first insulation material.

6. The method according to claim 1, further comprising applying a masking before the jetting or the spraying the first insulation material.

7. The method according to claim 1, wherein the first insulation material covers the first electronic component.

8. The method according to claim 1, further comprising applying a first protection layer outside the first shielding layer.

9. The method according to claim 1, wherein the first shielding layer is made of a first shielding material comprising metal particulates.

10. The method according to claim 9, wherein the metal particulates comprise copper particulates, silver particulates, zinc particulates, nickel particulates, or any combination of the foregoing.

11. The method according to claim 1, wherein the one or more electronic components comprises a second electronic component, the method comprising applying the first insulation layer outside the second electronic component.

12. The method according to claim 1, wherein the applied first insulation layer has a thickness less than 500 μm.

13. A method of manufacturing an electronic circuit of an audio device, the method comprising:
providing a circuit board;
mounting one or more electronic components including a first electronic component on the circuit board;
applying a first insulation layer outside the first electronic component; and
applying a first shielding layer outside the first insulation layer;
wherein the first insulation layer is made of a first insulation material comprising one or more polymers, and wherein the applied first insulation layer has a thickness less than 500 μm.

14. An electronic circuit for an audio device, the electronic circuit comprising:
a circuit board;
one or more electronic components including a first electronic component mounted on the circuit board;
a first insulation layer; and
a first shielding layer covering the first electronic component;
wherein the first insulation layer is between the first electronic component and the first shielding layer, wherein the first insulation layer has a thickness less than 500 μm.

15. The electronic circuit according to claim 14, wherein the one or more electronic components comprise a second electronic component mounted on the circuit board, and wherein the first shielding layer covers the second electronic component.

16. The electronic circuit according to claim 14, further comprising a first protection layer outside the first shielding layer.

17. The electronic circuit according to claim 14, wherein the circuit board comprises a ground connection contacting the first shielding layer.

18. The electronic circuit according to claim 14, wherein the first electronic component comprises a ground connection contacting the first shielding layer.

19. An audio device comprising:
a housing; and
the electronic circuit of claim 14, wherein the electronic circuit is in the housing.
